(19) United States
(12) Patent Application Publication
(10) Pub. No.: US 2025/0304231 A1
(43) Pub. Date: Oct. 2, 2025

(54) ELECTRIC OUTBOARD MOTOR

(71) Applicant: HONDA MOTOR CO., LTD., Tokyo (JP)

(72) Inventors: Atsuki Sugihara, Wako-shi (JP); Kazuki Ohno, Wako-shi (JP)

(21) Appl. No.: 18/617,673

(22) Filed: Mar. 27, 2024

(51) Int. Cl. B63H 21/17; B63H 20/32; H05K 7/20

(52) U.S. Cl. CPC B63H 21/17; B63H 20/32; H05K 7/20154; H05K 7/20172

(57) ABSTRACT

An electric outboard motor includes: a propulsion portion; an electric component; a blower fan for cooling; an electric component accommodation room; a fan accommodation room; and a partition wall. The propulsion portion generates a propulsion force. The electric component includes a control portion of the propulsion portion. The electric component accommodation room accommodates the electric component therein. The fan accommodation room accommodates the blower fan therein and has an opening portion through which external air flows in and flows out. The partition wall partitions the electric component accommodation room and the fan accommodation room, and the electric component is provided on a surface at an electric component accommodation room side. The blower fan is arranged in the fan accommodation room such that air blowing is directed toward the partition wall.

### BACKGROUND OF THE INVENTION

### Field of the Invention

The present invention relates to an electric outboard motor.

### Background Art

In recent years, as a drive source of an outboard motor, a drive source using an electric motor in place of an internal combustion engine such as a gasoline engine has been developed.

As an electric outboard motor of this type, an electric outboard motor is known in which an electric motor as a drive source is arranged on a case main body portion of an outboard motor case located at an upper side of a propulsion portion and above the water, and a drive force of the electric motor is transmitted to the propulsion portion via a drive shaft (for example, refer to Patent Document 1 (Japanese Unexamined Patent Application, First Publication No. 2005-153727)).

In the electric outboard motor described in Patent Document 1, an electric motor for driving, an electric component including a control portion of the electric motor, and the like are accommodated in the case main body portion of the outboard motor case. In a form of the electric outboard motor described in this document, the electric component or the like which tends to become a high temperature at the time of driving is cooled by a cooling mechanism of air cooling.

The cooling mechanism includes, an external air intake port provided on a wall of the case main body portion, an external air discharge port, and a blower fan for causing air to flow to the electric component or the like in the case main body portion. The external air intake port and the external air discharge port are arranged on a portion that does not submerge in water of a wall of the case main body portion. In this cooling mechanism, external air taken in from the external air intake port flows into the case main body portion, and the external air is blown to the electric component or the like by the blower fan. Then, the external air that has exchanged heat with the electric component or the like is discharged to the outside through the external air discharge port.

### SUMMARY OF THE INVENTION

In the electric outboard motor described in Patent Document 1, the external air flows in and is discharged from an electric component accommodation room (inside the case main body portion) by the external air intake port and the external air discharge port. However, since the external air intake port and the external air discharge port need to allow the inside of the electric component accommodation room (case main body portion) to communicate with the outside of the outboard motor, it is difficult to completely prevent outside water such as sea water or rain water from entering the electric component accommodation room. As a countermeasure, it is conceivable to employ a labyrinth structure for the external air intake port and the external air discharge port. However, in that case, a structure of an opening portion (an external air intake port, and an external air discharge port) for inflow and outflow of external air becomes complicated, and manufacturing at low cost becomes difficult.

Accordingly, the present invention is intended to provide an electric outboard motor capable of reliably cooling an electric component by air cooling in a state of preventing the inflow of outside water to the vicinity of the electric component without complicating a structure of an opening portion for inflow and outflow of external air.

An outboard motor according to an aspect of the present invention includes: a propulsion portion that generates a propulsion force; an electric component that includes a control portion of the propulsion portion; a blower fan for cooling; an electric component accommodation room that accommodates the electric component therein; a fan accommodation room that accommodates the blower fan therein and has an opening portion through which external air flows in and flows out; and a partition wall which partitions the electric component accommodation room and the fan accommodation room and in which the electric component is provided on a surface at a side of the electric component accommodation room, wherein the blower fan is arranged in the fan accommodation room such that air blowing is directed toward the partition wall.

In the electric outboard motor of the configuration described above, the electric component accommodation room and the fan accommodation room are partitioned by the partition wall, and the external air flows in and is discharged from the fan accommodation room through the opening portion. The external air that has flowed into fan accommodation room hits the partition wall by the air blowing by the blower fan. Thereby, the electric component provided on the partition wall is cooled via the partition wall.

In the case of the present configuration, the opening portion through which the external air flows in and is discharged communicates with the fan accommodation room, and the fan accommodation room and the electric component accommodation room are partitioned by the partition wall. Therefore, even when a complicated water entry prevention structure such as a labyrinth structure is not employed for the opening portion for inflow and outflow of the external air, it is possible to prevent the inflow of outside water to the vicinity of the electric component.

### Effects of the Invention

According to the present invention, it is possible to reliably cool the electric component by air cooling in a state of preventing the inflow of the outside water to the vicinity of the electric component without complicating the structure of the opening portion for inflow and outflow of the external air.

### BRIEF DESCRIPTION OF THE DRAWINGS

FIG. 1 is a schematic side view of an outboard motor of a first embodiment.

FIG. 2 is a perspective view of a main body unit in the outboard motor of the first embodiment.

FIG. 3 is a bottom view of the main body unit in the outboard motor of the first embodiment.

FIG. 4 is a longitudinal cross-sectional view of the main body unit in the outboard motor of the first embodiment.

FIG. 5 is a bottom view of the main body unit from which part of members is removed in the outboard motor of the first embodiment.

FIG. 6 is a front view of the main body unit in the outboard motor of the first embodiment.

FIG. 7 is a perspective view of a main body unit from which part of members is removed in an outboard motor of a second embodiment.

FIG. 8 is a bottom view of a main body unit from which part of members is removed in an outboard motor of a third embodiment.

### EMBODIMENTS

Hereinafter, embodiments of the present invention will be described with reference to the drawings. In the embodiments, common portions are denoted by the same reference numerals, and redundant descriptions are partially omitted.

Further, at appropriate positions in the drawings, an arrow FR that indicates a forward side in a propulsion direction of an electric outboard motor 1, an arrow UP that indicates a vertically upward direction, and a LH that indicates a leftward direction in facing the propulsion direction of the electric outboard motor 1 are shown.

### First Embodiment

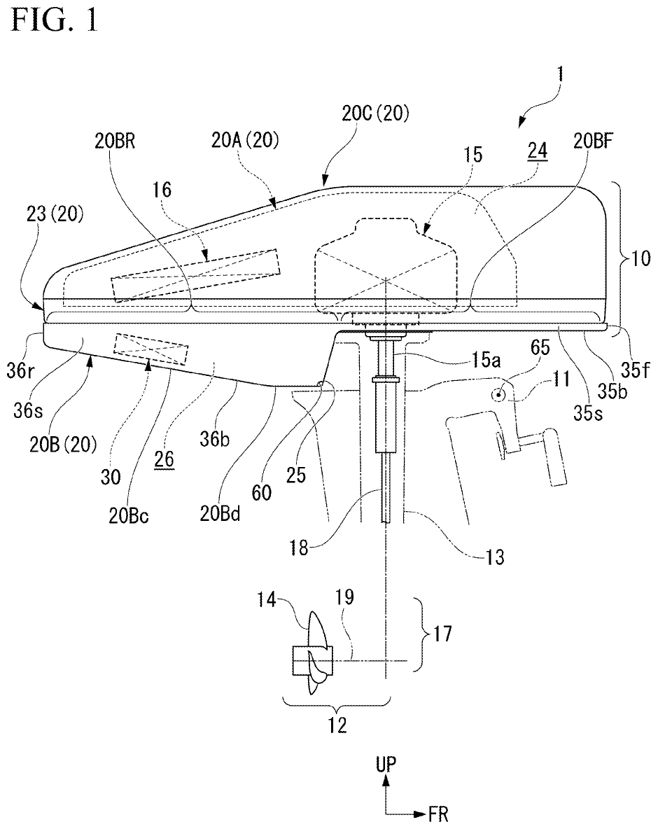

FIG. 1 is a schematic side view of the electric outboard motor 1 of the present embodiment.

The electric outboard motor 1 includes a main body unit 10 as an upper unit, an attachment portion 11 for attaching the main body unit 10 to a hull (not shown), a lower unit 12 that accommodates a main portion of a propulsion mechanism, and a connection portion 13 that connects the main body unit 10 to the lower unit 12. The lower unit 12 and the connection portion 13 may be one unit.

The attachment portion 11 is fixed to a transom (not shown) at a rear portion of the hull. A swivel portion (not shown) that rotatably supports the connection portion 13 for steering and a tilt mechanism portion (not shown) that supports the connection portion 13 swingably upward and downward for a tilt operation are provided on the attachment portion 11. The tilt mechanism portion is a mechanism for appropriately switching between a first posture, which is a posture of the electric outboard motor 1 in which a thrust force of a ship is directed in a horizontal direction in a ship stop state, and a second posture in which a rear portion of the electric outboard motor 1 tilts upward or downward further than in the first posture.

Reference numeral 65 in FIG. 1 indicates a tilt shaft of the tilt mechanism portion.

The electric outboard motor 1 includes a screw 14 that is submerged in outside water and generates a propulsion force, an electric motor 15 that drives the screw 14, an electric component 16 that includes a control portion (control portion of a propulsion portion) of the electric motor 15 or the like, and a power transmission mechanism 17 that transmits a power of the electric motor 15 to the screw 14. In the present embodiment, the screw 14, the electric motor 15, the power transmission mechanism 17, and the like constitute the propulsion portion in the electric outboard motor 1. The power transmission mechanism 17 includes a drive shaft 18 that is coaxially connected to an output shaft 15a of the electric motor 15, a speed reduction portion (not shown) that reduces the speed of rotation of the drive shaft 18 and transmits the rotation to a screw shaft 19, and the like. The screw 14 and part of a speed reduction mechanism are provided on the lower unit 12 that is submerged in the outside water at the time of navigation, and the electric motor 15 and the electric component 16 are provided on the main body unit 10 located above the water at the time of navigation.

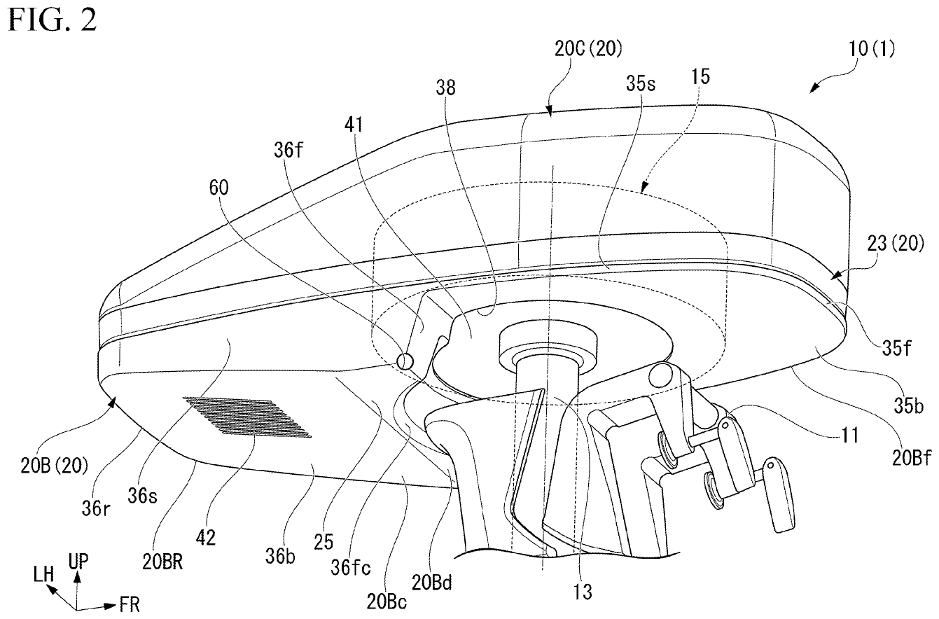

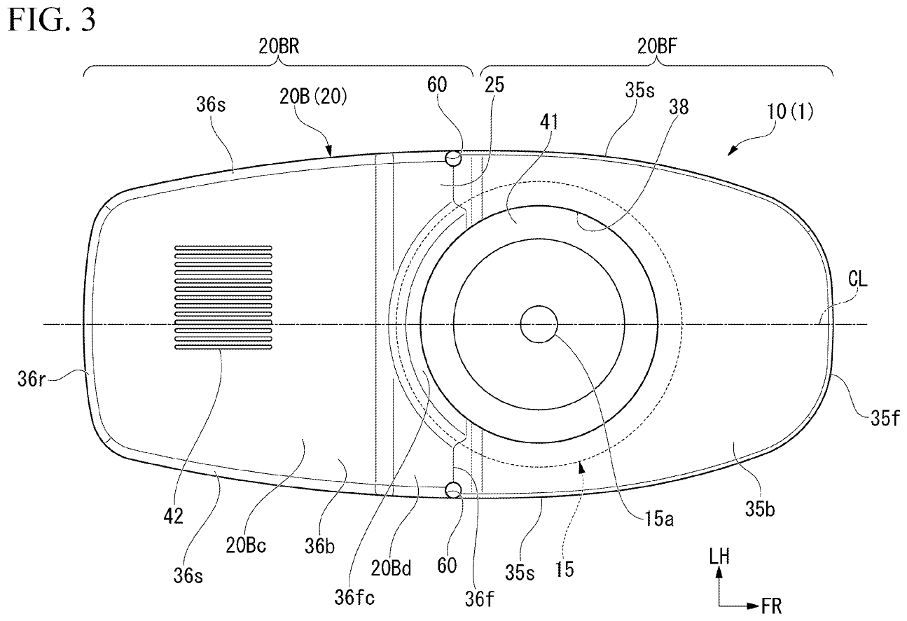

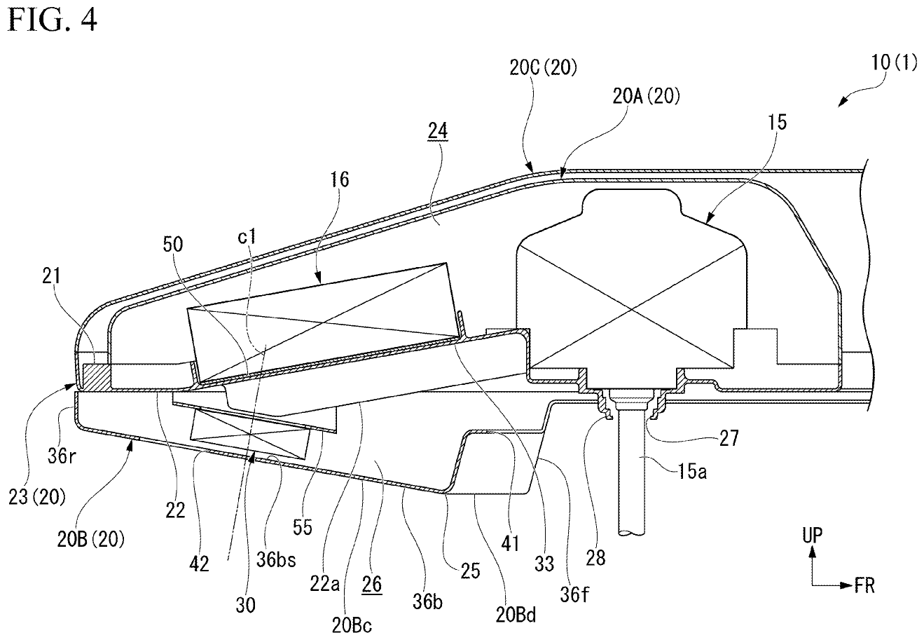

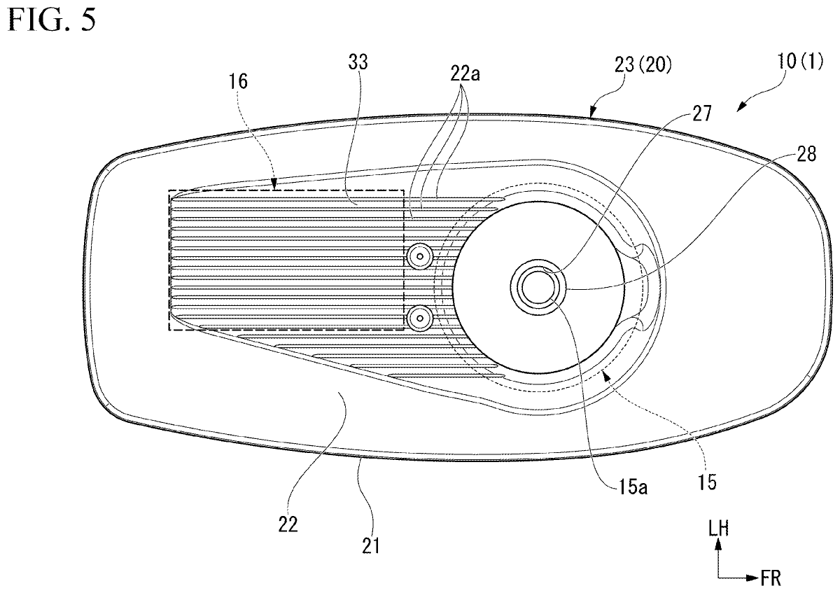

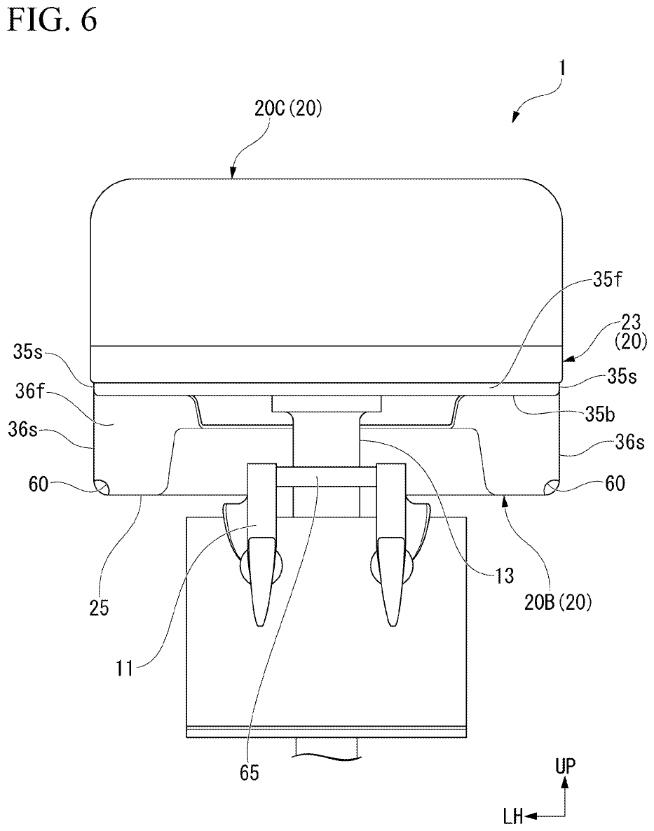

FIG. 2 is a perspective view of the main body unit 10 seen from a forward leftward downward direction, and FIG. 3 is a bottom view of the main body unit 10. FIG. 4 is a longitudinal cross-sectional view in which the main body unit 10 is cut along a forward-rearward direction at a center CL in a width direction. FIG. 5 is a bottom view of the main body unit 10 from which part of members (a lower case 20B described later) id removed, and FIG. 6 is a front view of the main body unit 10.

The main body unit 10 includes an outboard motor case 20. As shown in FIG. 4, the outboard motor case 20 includes a base block 23, an upper case 20A, a lower case 20B, and an outer cover 20C.

The base block 23 is formed in a substantially rectangular shape in a top view elongated in the forward-rearward direction as compared to the width direction. However, four corners of the base block 23 in the top view have a moderately rounded shape. The base block 23 includes a thick circumferential edge wall 21 arranged in a circumferential region of the base block 23 and a partition wall 22 that is provided to extend in an inner region of the circumferential edge wall 21. The partition wall 22 is formed such that a thickness in an upward-downward direction is thinner than that of the circumferential edge wall 21. The base block 23 is formed of a metal material such as an aluminum alloy having good thermal conductivity.

The upper case 20A is fixed to the circumferential edge wall 21 so as to cover an upper side of the partition wall 22. The upper case 20A is formed in a shape that is smaller than the base block 23 and is substantially the same shape in a top view as the base block 23. The upper case 20A and the partition wall 22 of the base block 23 form an electric component accommodation room 24. The upper case 20A is formed of a hard resin material. A space between the upper case 20A and the base block 23 is sealed by a seal member (not shown) having an annular shape. Thereby, a watertight property in the electric component accommodation room 24 is ensured.

The lower case 20B is fixed to the circumferential edge wall 21 of the base block 23 so as to cover a lower side of the base block 23. The lower case 20B has a front case region 20BF in which an upward-downward width from a lower end of the circumferential edge wall 21 of the base block 23 is narrow, and a rear case region 20BR in which an upward-downward width from the lower end of the circumferential edge wall 21 of the base block 23 is wide. The front case region 20BF is arranged on a forward side in the forward-rearward direction of the lower case 20B, and the rear case region 20BR is arranged on a rearward side in the forward-rearward direction of the lower case 20B.

The front case region 20BF has right and left side walls 35s and a front wall 35f in which an upward-downward size is short as compared to the rear case region 20BR, and a front-side bottom wall 35b that covers a lower side of a space surrounded by the right and left side walls 35s and the front wall 35f.

Further, the rear case region 20BR has right and left side walls 36s and a rear wall 36r in which an upward-downward size is long as compared to the front case region 20BF, a front wall 36f that extends downward from a rear end portion of the front-side bottom wall 35b of the front case region 20BF, and a rear-side bottom wall 36b that covers a lower side of a space surrounded by the right and left side walls 36s, the rear wall 36r, and the front wall 36f. The rear-side bottom wall 36b of the rear case region 20BR is located at a lower position than the front-side bottom wall 35b of the front case region 20BF. A curved recess portion 36fc that is curved in an arc shape toward the rearward side is provided in a middle region in the width direction of the front wall 36f of the rear case region 20BR.

In the present embodiment, the right and left side walls 36s, the rear wall 36r, the front wall 36f, and rear-side bottom wall 36b of the rear case region 20BR constitute a recess portion 25 in the lower case 20B. The recess portion 25 and the partition wall 22 of the base block 23 form a main portion of a fan accommodation room 26.

The lower case 20B is formed of a hard resin material similarly to the upper case 20A. An outer circumferential edge portion on the lower side of the lower case 20B is reinforced by a metal material such as an aluminum alloy. Thereby, the stiffness of the lower case 20B when a user puts his/her hand on an edge portion on the lower surface side of the lower case 20B or the like at the time of carrying or the like is ensured.

The partition wall 22 of the base block 23 partitions the electric component accommodation room 24 and the fan accommodation room 26 in the upward-downward direction.

The outer cover 20C is fixed to the circumferential edge wall 21 of the base block 23 so as to cover the circumference and the upper side of the upper case 20A. The outer cover 20C is formed of a metal material such as aluminum alloy, protects an upper region of the outboard motor case 20 from the outside, and also functions as a design surface for improving the appearance.

As shown in FIG. 4 and FIG. 5, the electric motor 15 is fixedly provided at a slightly further forward position than a middle position in the forward-rearward direction on an upper surface of the partition wall 22 of the base block 23. The electric motor 15 is arranged at a middle position in the width direction of the upper surface of the partition wall 22. A penetration hole 27 for allowing the output shaft 15a of the electric motor 15 to protrude downward is formed at a middle of the partition wall 22 at the arrangement position of the electric motor 15. The penetration hole 27 is formed in a boss portion 28 that has a cylindrical shape and protrudes to a lower side of the partition wall 22. The connection portion 13 having a cylindrical shape shown in FIG. 1 and FIG. 2 is connected to the boss portion 28.

Further, as shown in FIG. 4, an inclination wall portion 33 in which an upper surface is inclined downward toward the rearward side is provided on the upper surface of the partition wall 22 of the base block 23 at a further rearward position than an arrangement portion of the electric motor 15. The electric component 16 is fixedly provided on an upper surface side of the inclination wall portion 33 via a heat transfer sheet 50 (heat transfer material) such as a silicon sheet. The electric component 16 is a component that easily generates heat and includes at least a control portion (a drive circuit) such as the electric motor 15. The heat generated by the electric component 16 is transferred to the inclination wall portion 33 of the partition wall 22 via the heat transfer sheet 50.

A plurality of fin portions 22a are provided to protrude on a lower surface of the inclination wall portion 33 so as to face the inside of the fan accommodation room 26. Each fin portion 22a is formed integrally with the inclination wall portion 33 (the partition wall 22). In the case of the present embodiment, the fin portion 22a is constituted of a plate-like piece extending along the forward-rearward direction and the upward-downward direction. The fin portions 22a extend long in the forward-rearward direction and are arranged to be spaced at substantially constant intervals in the width direction. Further, front ends of the plurality of fin portions 22a extend to the arrangement portion of the electric motor 15. The front ends of the plurality of fin portions 22a are arranged such that front end positions are displaced in an arc shape along an outer circumferential portion having a circular shape of the electric motor 15.

As shown in FIG. 4, the electric component 16 is provided on the inclination wall portion 33 of the partition wall 22 such that at least part of the electric component 16 faces the fin portion 22a so as to interpose the partition wall 22. In the present embodiment, part of a rear region of the electric component 16 is offset to a rearward side relative to the fin portion 22a, and the rest of the rear region of the electric component 16 is arranged at an upper position of the fin portion 22a.

A blower fan 30 that blows air toward the partition wall 22 is provided in the fan accommodation room 26 formed between the partition wall 22 and the lower case 20B. The blower fan 30 is fixed to a lower surface of the partition wall 22 via a bracket 55 made of a metal. The blower fan 30 is supported by the bracket 55 so as to be spaced upward by a predetermined distance relative to a bottom surface 36bs of the rear-side bottom wall 36b of the lower case 20B. The blower fan 30 is arranged at a position where part of the blower fan 30 overlaps rear regions of the plurality of fin portions 22a of the partition wall 22 in the forward-rearward direction.

Further, the blower fan 30 is inclined such that an air blowing direction faces a direction of the front upper fin portion 22a and such that an air blowing axis cl (refer to FIG. 4) faces a forward upward direction. In other words, the blower fan 30 is arranged such that the air blowing axis cl is inclined so as to face a side (forward side) of the electric component 16 and the electric motor 15 with respect to the vertical direction. Accordingly, the blower fan 30 is provided such that the air blowing direction faces a side where the electric component 16 and the electric motor 15 are arranged across the partition wall 22. The rear-side bottom wall 36b of the lower case 20B located at a lower position than the blower fan 30 is inclined toward a forward downward direction so as to be substantially parallel to the lower surface of the blower fan 30.

In the case of the present embodiment, since the plurality of fin portions 22a are provided on the lower surface of the inclination wall portion 33 so as to extend in the forward-rearward direction and the upward-downward direction, the air by the blower fan 30 smoothly flows also in the direction of the arrangement portion of the electric motor 15 along the fin portion 22a.

A first opening portion 41 and a second opening portion 42 that allow external air to flow into and be discharged from the fan accommodation room 26 are provided on the lower case 20B.

The first opening portion 41 is arranged in a region through which the output shaft 15a of the electric motor 15 at a further forward side than the recess portion 25 of the lower case 20B and the connection portion 13 having a substantially cylindrical shape are inserted. More specifically, a penetration hole 38 having a substantially circular shape and a large diameter is formed at a position that extends from the front-side bottom wall 35b of the front case region 20BF of the lower case 20B to part of the front wall 36f (curved recess portion 36fc) of the rear case region 20BR, and the output shaft 15a and the connection portion 13 are inserted through a middle region of the penetration hole 38. Part of the penetration hole 38 is formed to span the curved recess portion 36fc of the front wall 36f. The first opening portion 41 is constituted of a gap having a substantially annular shape between the penetration hole 38 and the connection portion 13. Therefore, the first opening portion 41 also serves as a shaft insertion portion through which the output shaft 15a of the electric motor 15 is inserted. However, although the output shaft 15a of the electric motor 15 is inserted through the first opening portion 41 that also serves as the shaft insertion portion in the present embodiment, when the protrusion length of the output shaft 15 of the electric motor 15 is short, the drive shaft 18 or a link shaft that connects the output shaft 15a to the drive shaft 18 may be inserted through the first opening portion 41 that also serves as the shaft insertion portion. That is, the shaft inserted through the shaft insertion portion (first opening portion 41) is not limited to the output shaft 15a of the electric motor 15 and may be the drive shaft 18, the link shaft, or the like as long as the shaft is a shaft on the output side of the electric motor 15.

Further, the first opening portion 41 having an annular shape is arranged in a region (front-side region) closer to the attachment portion 11 than at least part of the electric motor 15 and the electric component 16.

The second opening portion 42 is formed on the rear-side bottom wall 36b of the recess portion 25 of the lower case 20B. More specifically, the second opening portion 42 is arranged in a region of the rear-side bottom wall 36b of the lower case 20B at a further rearward position than a center position in the forward-rearward direction of the electric component 16. In the case of the present embodiment, part of the front end side of the second opening portion 42 is arranged at a position that overlaps a rear end portion of the electric component 16 in the forward-rearward direction. As shown in FIG. 3, the second opening portion 42 is constituted of a plurality of slits provided along the forward-rearward direction in a substantially rectangular region of the rear-side bottom wall 36b.

The second opening portion 42 constituted of the plurality of slits is arranged in a region (rear-side region) that is farther away from the attachment portion 11 than at least part of the electric motor 15 and the electric component 16.

Further, a pair of drain holes 60 are formed on the rear-side bottom wall 36b that constitutes part of the recess portion 25 of the lower case 20B. The drain hole 60 is formed on each of right and left front-side corners of the rear-side bottom wall 36b of the recess portion 25. More specifically, the pair of drain holes 60 are provided at a front end side of the recess portion 25 and at outer end positions at both sides in the width direction across a steering shaft (drive shaft 18).

The rear-side bottom wall 36b of the lower case 20B includes a downward inclination portion 20Bbc that is inclined downward from the rear end side toward the forward side, and a horizontal portion 20Bbd that extends forward horizontally from a front end of the downward inclination portion 20Bbc. The pair of drain holes 60 are provided on the rear-side bottom wall 36b of the lower case 20B at right and left end positions on the front end side of the horizontal portion 20Bbd. That is, the pair of drain holes 60 are arranged on the rear-side bottom wall 36b at right and left end positions of a region that becomes a lowermost end when the electric outboard motor 1 is in the first posture.

As described above, the first posture is a posture of the electric outboard motor 1 in which the thrust force of the ship is directed in the horizontal direction in the ship stop state. When the posture of the electric outboard motor 1 is the first posture, the drive shaft 18 faces a vertically downward direction. The horizontal portion 20Bbd becomes horizontal in this state.

Although the rear-side bottom wall 36b of the lower case 20B of the present embodiment has a shape constituted of the downward inclination portion 20Bbc and the horizontal portion 20Bbd, the shape of the rear-side bottom wall 36b is not limited to this shape. The rear-side bottom wall 36b may have, for example, a shape including a curved portion or the like. Regardless of the shape of the rear-side bottom wall 36b, it is desirable that the rear-side bottom wall 36b is provided in a region where the inner surface is at the lowest position when the posture of the electric outboard motor 1 is the first posture.

As described above, in the electric outboard motor 1 of the present embodiment, the electric component accommodation room 24 and the fan accommodation room 26 of the main body unit 10 are partitioned by the partition wall 22, and the external air flows in and is discharged from the fan accommodation room 26 through the opening portions (the first opening portion 41 and the second opening portion 42). At this time, the external air that has flowed into the fan accommodation room 26 hits the lower surface of the partition wall 22 by the air blowing by the blower fan 30, and the electric component 16 provided on the upper surface side of the partition wall 22 is cooled via the partition wall 22.

Further, in the electric outboard motor 1 of the present embodiment, the opening portion (the first opening portion 41 and the second opening portion 42) through which the external air flows in and is discharged communicates with the fan accommodation room 26, and the fan accommodation room 26 and the electric component accommodation room 24 are partitioned by the partition wall 22. Therefore, even when a complicated water entry prevention structure such as a labyrinth structure is not employed for the opening portion (the first opening portion 41 and the second opening portion 42) for inflow and outflow of the external air, it is possible to prevent the inflow of outside water to the vicinity of the electric component 16.

Accordingly, when the electric outboard motor 1 of the present embodiment is employed, it is possible to reliably cool the electric component 16 by air cooling in a state of preventing the inflow of the outside water to the vicinity of the electric component 16 without complicating the structure of the opening portion for inflow and outflow of the external air.

Further, in the electric outboard motor 1 of the present embodiment, the fin portion 22a for cooling that protrudes to face the fan accommodation room 26 side is provided on the partition wall 22. Therefore, by the fin portion 22a for cooling, a surface area of a portion of the partition wall 22 facing the fan accommodation room 26 side is increased, and the partition wall 22 is efficiently cooled by the external air flowing in the fan accommodation room 26. Accordingly, when the present configuration is employed, it becomes possible to further efficiently cool the electric component 16.

Further, in the electric outboard motor 1 of the present embodiment, at least part of the electric component 16 is arranged at a position that faces the fin portion 22a for cooling across the partition wall 22. Therefore, the electric component 16 is arranged such that at least part of the electric component 16 overlaps a region of the partition wall 22 that is efficiently cooled by the fin portion 22a for cooling. Accordingly, when the present configuration is employed, it becomes possible to further efficiently cool the electric component 16.

Further, in the electric outboard motor 1 of the present embodiment, the blower fan 30 is provided such that the air blowing direction faces the direction of the fin portion 22a for cooling. Therefore, forced air by the blower fan 30 reliably hits the fin portion 22a for cooling that is arranged so as to overlap at least part of the electric component 16. Accordingly, when the present configuration is employed, it becomes possible to further efficiently cool the electric component 16.

Further, in the electric outboard motor 1 of the present embodiment, the electric motor 15 for driving is mounted on the upper surface of the partition wall 22 in the electric component accommodation room 24. Therefore, it becomes possible to reliably cool the electric motor 15, which is likely to generate heat at the time of driving, via the partition wall 22 similarly to the electric component 16.

Further, in the electric outboard motor 1 of the present embodiment, the first opening portion 41 for inflow and outflow of the external air is arranged in a region closer to the attachment portion 11 than at least part of the electric motor 15 and the electric component 16, and the second opening portion 42 for inflow and outflow of the external air is arranged in a region farther away from the attachment portion 11 than at least part of the electric motor 15 and the electric component 16. Therefore, the external air flows into the fan accommodation room 26 from one of the first opening portion 41 and the second opening portion 42, flows through the fan accommodation room 26, and flows out to the outside from the other of the first opening portion 41 and the second opening portion 42. At this time, at least part of the electric motor 15 and the electric component 16 are arranged to face a flow path between the first opening portion 41 and the second opening portion 42 across the partition wall 22. Accordingly, when the present configuration is employed, the electric component 16 and electric motor 15 are efficiently cooled by the external air flowing through the flow path described above, and the cooling performance of the electric component 16 and the electric motor 15 is further enhanced.

Further, in the electric outboard motor 1 of the present embodiment, the first opening portion 41 as the one opening portion is formed to also serve as the shaft insertion portion through which the shaft on the output side of the electric motor 15 is inserted. In this case, a relatively large opening portion for inflow and outflow of external air can be easily ensured on the lower side of the fan accommodation room 26, and it is possible to easily enhance the cooling performance of the electric component 16 and the electric motor 15.

Specifically, in the present embodiment, since the first opening portion 41 located on the forward side in the travel direction of the ship is formed so as to span part of the front wall 36f of the recess portion of the lower case 20B, travel wind easily flows into the fan accommodation room 26 through the first opening portion 41. Accordingly, it is also possible to enhance the cooling performance of the electric component 16 and the electric motor 15.

Further, in the electric outboard motor 1 of the present embodiment, the blower fan 30 is arranged such that the air blowing axis cl is inclined so as to face the side of the electric motor 15 with respect to the vertical direction. In this case, since the air blowing of the blower fan 30 is directed in the direction of the electric motor 15 across the partition wall 22, it becomes possible to efficiently cool the electric motor 15 that generates heat at the time of driving.

Specifically, in the present embodiment, since the inclination wall portion 33 inclined upward from the blower fan 30 toward the arrangement position of the electric motor 15 is provided on the partition wall 22, it is possible to efficiently cool the electric motor 15 by the external air blown by the blower fan 30. That is, not only the lower surface of the electric motor 15 but also the vicinity of the circumference of the lower region of the electric motor 15 can be cooled by the air blowing of the blower fan 30.

Further, in the present embodiment, since the plurality of fin portions 22a for cooling that are provided to protrude on the lower surface of the inclination wall portion 33 also functions as a guide portion that guides the air blowing in the direction of the electric motor 15, it is possible to further enhance the cooling efficiency of the electric motor 15.

Further, in the electric outboard motor 1 of the present embodiment, the drain hole 60 is provided on the rear-side bottom wall 36b of the lower case 20B that forms the fan accommodation room 26 together with the partition wall 22. Therefore, even when the outside water enters the fan accommodation room 26 through the first opening portion 41 or the second opening portion 42, the outside water can be discharged to the outside through the drain hole 60 provided on the rear-side bottom wall 36b of the lower case 20B.

Further, in the electric outboard motor 1 of the present embodiment, the drain hole 60 is provided on each of a first side and a second side across the center CL (a position where the drive shaft 18 is arranged) in the width direction of the rear-side bottom wall 36b of the lower case 20B. Therefore, for example, even when a tilt-up operation or a tilt-down operation is performed while steering the outboard motor, the outside water can be reliably discharged to the outside from the drain hole 60 at any of the first side and the second side in the width direction of the rear-side bottom wall 36b.

Further, in the electric outboard motor 1 of the present embodiment, the drain hole 60 is provided at a front end side of the recess portion 25 recessed to a lower side of the lower case 20B and at an outer end position at both sides in the width direction. Therefore, when the tilt-up operation is performed while steering the outboard motor, it becomes possible to further reliably discharge the outside water in the fan accommodation room 26.

In the present embodiment, when the electric outboard motor 1 is in the first posture and is not tilted up or is not tilted down, the rear-side bottom wall 36b (downward inclination portion 20Bbc) of the recess portion 25 is formed so as to incline in the forward side. Therefore, even when the electric outboard motor 1 is in the first posture, the outside water in the fan accommodation room 26 can be favorably discharged to the outside through the right and left drain holes 60.

Further, in the electric outboard motor 1 of the present embodiment, the blower fan 30 is fixed to the partition wall 22 via the bracket 55 so as to be separated from the bottom surface 20Bbs of the fan accommodation room 26. Therefore, even when the outside water enters the fan accommodation room 26, it is difficult for the outside water to enter the inside of the blower fan 30. Accordingly, when the present configuration is employed, it becomes possible to stably maintain the performance of the blower fan 30 in a good condition.

Further, in the electric outboard motor 1 of the present embodiment, the electric component 16 is mounted on the partition wall 22 via the heat transfer sheet 50 which is a heat transfer material. Therefore, the heat transfer between the electric component 16 and the partition wall 22 can be constantly favorably maintained by the heat transfer sheet 50. Accordingly, when the present configuration is employed, the heat generated by the electric component 16 is favorably released into the fan accommodation room 26 through the partition wall 22, it becomes possible to efficiently cool the electric component 16.

### Second Embodiment

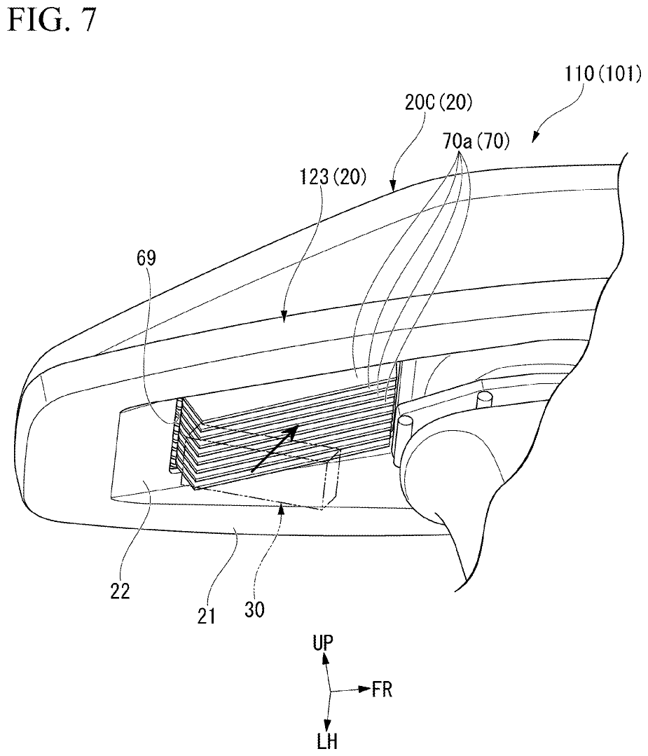

FIG. 7 is a perspective view of a main body unit 110 from which part of components (lower cover) is removed in an electric outboard motor 101 of the present embodiment.

The basic configuration of the electric outboard motor 101 of the present embodiment is similar to that of the first embodiment. However, the electric outboard motor 101 of the present embodiment differs from that of the first embodiment in that the heat transfer block 70 is attached to the lower region of the electric component, and part of the heat transfer block 70 penetrates through part of the partition wall 22 of a base block 123.

As shown in FIG. 7, a penetration hole 69 having a rectangular shape is formed on the partition wall 22 of the base block 123. A plurality of cooling fins 70a are provided to protrude on the heat transfer block 70 attached to the electric component. Each cooling fin 70a of the heat transfer block 70 is formed in a plate shape so as to extend in the forward-rearward direction and the upward-downward direction. The plurality of cooling fins 70a of the heat transfer block 70 protrude into a fan accommodation room at a lower side through the penetration hole 69. A space between the penetration hole 69 and the heat transfer block 70 is sealed by a seal material (not shown). Thereby, the electric component accommodation room 24 at an upper side of the partition wall 22 is reliably separated in a seal state from the fan accommodation room 26 at a lower side of the partition wall 22. Accordingly, it is possible to prevent the outside water from entering the electric component accommodation room 24 from the fan accommodation room 26 through the gap between the penetration hole 65 and the heat transfer block 70.

In the present embodiment, a configuration is employed in which the electric component is cooled by the external air via the cooling fin 70a (heat transfer block 70) protruding into the fan accommodation room.

Further, the blower fan 30 is arranged in the fan accommodation room similarly to the first embodiment. The blower fan 30 is arranged to be inclined forward and upward such that an air blowing direction faces a direction of the cooling fin 70a and the electric component at the upper side of the cooling fin 70a.

Since the basic configuration of the electric outboard motor 101 of the present embodiment is similar to that of the first embodiment, basic effects similar to those of the first embodiment described above can be obtained.

However, in the electric outboard motor 101 of the present embodiment, since the cooling fin 70a that protrudes from the partition wall 22 into the fan accommodation room is provided on the heat transfer block 70 to which the electric components is attached, the electric component in the electric component accommodation room can be efficiently cooled by the external air in the fan accommodation room. Accordingly, when the present configuration is employed, it is possible to further enhance the cooling performance of the electric component.

Further, in the electric outboard motor 101 of the present embodiment, the blower fan 30 is provided such that the air blowing direction faces the direction of the cooling fin 70a. Therefore, forced air by the blower fan 30 reliably hits the cooling fin 70a of the heat transfer block 70. Accordingly, when the present configuration is employed, it becomes possible to further efficiently cool the electric component.

### Third Embodiment

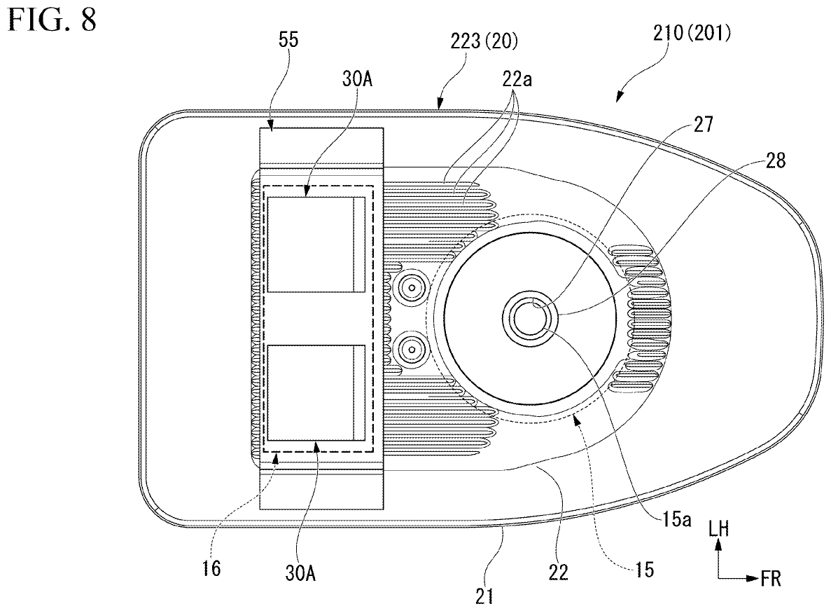

FIG. 8 is a bottom view of a main body unit 210 from which part of components (lower cover) is removed in an electric outboard motor 201 of the present embodiment.

The basic configuration of the electric outboard motor 201 of the present embodiment is similar to that of the first embodiment. However, the electric outboard motor 201 of the present embodiment differs from that of the first embodiment in that an electric component 16 elongated in one direction is arranged laterally along the width direction of a main body unit 210, and a pair of blower fans 30A are arranged to be aligned in the width direction of the main body unit 210 below the partition wall 22. Also in the case of the present embodiment, the pair of blower fans 30A are fixed to the partition wall 22 via the bracket 55.

Since the basic configuration of the electric outboard motor 201 of the present embodiment is similar to that of the first embodiment, basic effects similar to those of the first embodiment described above can be obtained.

However, in the electric outboard motor 201 of the present embodiment, since the electric component 16 elongated in one direction is arranged laterally along the width direction of the main body unit 210, and the pair of blower fans 30A are arranged to be aligned in the longitudinal direction of the electric component 16, it is possible to sufficiently shorten the length in the forward-rearward direction of the main unit 210. Further, since the pair of blower fans 30A are arranged along the longitudinal direction of the electric component 16, it is possible to further enhance the cooling performance of the electric component 16.

The present invention is not limited to the embodiments described above, and various design changes can be made without departing from the scope of the present invention. For example, in the embodiment described above, the first opening portion 41 and the second opening portion 42 are provided as the opening portion for inflow and outflow of external air on the lower case 20B that forms the fan accommodation room 26. However, the quantity of the opening portion is not limited to two, and may be one or three or more.

Further, in the embodiment described above, the first opening portion 41 is formed so as to overlap part of the electric motor 15 in the forward-rearward direction; however, the first opening portion 41 may be arranged at a further forward side than the electric motor 15 so as not to overlap the electric motor 15 in the forward-rearward direction. Further, in the embodiment described above, the second opening portion 42 is formed so as to overlap part of the electric component 16 in the forward-rearward direction; however, the second opening portion 42 may be arranged at a further rearward side than the electric component 16 so as not to overlap the electric component 16 in the forward-rearward direction.

### DESCRIPTION OF REFERENCE NUMERALS

1, 101, 201 Electric outboard motor
11 Attachment portion
14 Screw (propulsion portion)
15 Electric motor (propulsion portion)
15a Output shaft
16 Electric component
17 Power transmission mechanism (propulsion portion)
20B Lower case
22 Partition wall
22a Fin portion
24 Electric component accommodation room
25 Recess portion
26 Fan accommodation room
30, 30A Blower fan
36b Rear bottom wall (bottom wall)
36bs Bottom surface
41 First opening portion (opening portion)
42 Second opening portion (opening portion)
50 Heat transfer sheet (heat transfer material)
55 Bracket
60 Drain hole
70 Heat transfer block
70a Cooling fin

What is claimed is:

1. An electric outboard motor comprising:
a propulsion portion that generates a propulsion force;
an electric component that includes a control portion of the propulsion portion;
a blower fan for cooling;
an electric component accommodation room that accommodates the electric component therein;
a fan accommodation room that accommodates the blower fan therein and has an opening portion through which external air flows in and flows out; and
a partition wall which partitions the electric component accommodation room and the fan accommodation room and in which the electric component is provided on a surface at a side of the electric component accommodation room,
wherein the blower fan is arranged in the fan accommodation room such that air blowing is directed toward the partition wall.

2. The electric outboard motor according to claim 1,
wherein a fin portion for cooling that protrudes to face a side of the fan accommodation room is provided on the partition wall.

3. The electric outboard motor according to claim 2,
wherein at least part of the electric component is arranged at a position that faces the fin portion across the partition wall.

4. The electric outboard motor according to claim 3,
wherein the blower fan is provided such that an air blowing direction is directed toward the fin portion.

5. The electric outboard motor according to claim 1,
wherein the electric component is provided on the partition wall via a heat transfer block having a cooling fin, and
the heat transfer block is provided on the partition wall such that the cooling fin protrudes from the partition wall into the fan accommodation room.

6. The electric outboard motor according to claim 5,
wherein the blower fan is provided such that an air blowing direction is directed toward the cooling fin.

7. The electric outboard motor according to claim 1,
wherein the propulsion portion comprises an electric motor, and
the electric motor is arranged in the electric component accommodation room and is provided on the partition wall.

8. The electric outboard motor according to claim 7, comprising:
an attachment portion for attaching the electric outboard motor to a hull,
wherein the opening includes a first opening portion and a second opening portion that are arranged to be spaced from each other in the fan accommodation room, and
one of the first opening portion and the second opening portion is arranged in a region closer to the attachment portion than at least part of the electric motor and the electric component, and another of the first opening portion and the second opening portion is arranged in a region farther away from the attachment portion than at least part of the electric motor and the electric component.

9. The electric outboard motor according to claim 7,
wherein the opening portion includes a first opening portion and a second opening portion that are arranged to be spaced from each other in the fan accommodation room, and
any one of the first opening portion and the second opening portion serves as a shaft insertion portion through which a shaft on an output side of the electric motor is inserted.

10. The electric outboard motor according to claim 7,
wherein the blower fan is arranged such that an air blowing axis is inclined so as to face a side of the electric motor with respect to a vertical direction.

11. The electric outboard motor according to claim 1,
wherein the fan accommodation room is formed to be surrounded by the partition wall and a lower case that covers a lower side of the partition wall, and
a drain hole is formed on a bottom wall of the lower case.

12. The electric outboard motor according to claim 11,
wherein the drain hole is provided on each of a first side and a second side across a center in a width direction of the bottom wall.

13. The electric outboard motor according to claim 12,
wherein the lower case includes a recess portion which is recessed to a lower side in a concave shape and in which the blower fan is arranged, and
the drain hole is provided at a front end side of the recess portion and at an outer end position at both sides in the width direction.

14. The electric outboard motor according to claim 1,
wherein the blower fan is fixed to the partition wall via a bracket so as to be separated from a bottom surface of the fan accommodation room.

15. The electric outboard motor according to claim 1,
wherein the electric component is mounted on the partition wall via a heat transfer material.
